(19) United States
(12) Patent Application Publication
(10) Pub. No.: US 2003/0104122 A1
(43) Pub. Date: Jun. 5, 2003

(54) System and method for treating, such as insulating, piezoelectric components, such as piezoelectric micro-actuators for use in magnetic hard disk drives

(76) Inventors: Masashi Shiraishi, Kowloon (HK); Ming Gao Yao, Dongguan City (HK); Tamon Kasajima, Kowloon (CN)

Correspondence Address: KENYON & KENYON (SAN JOSE), 333 WEST SAN CARLOS ST., SUITE 600, SAN JOSE, CA, 95110, US

(21) Appl. No.: 10/097,851

(22) Filed: Mar. 13, 2002

(30) Foreign Application Priority Data
Dec. 3, 2001 (WO) PCT/CN01/01597

(51) Int. Cl. B05D 1/18; B05D 5/12; C23C 16/26; B05D 3/06; C23C 16/00

(52) U.S. Cl. 427/100; 427/558; 427/255.28; 427/430.1; 427/249.7

(57) ABSTRACT

A system and method for treating, such as insulating, piezoelectric components, such as piezoelectric micro-actuators for use in magnetic hard disk drives is disclosed, different embodiments involving material dipping, spraying, pin application, and chemical vapor deposition.

### BACKGROUND INFORMATION

The present invention relates to magnetic hard disk drives. More specifically, the present invention relates to a system and method for treating, such as insulating, piezoelectric components, such as piezoelectric micro-actuators.

In the art today, different methods are utilized to improve recording density of hard disk drives. FIG. 1 provides an illustration of a typical drive arm configured to read from and write to a magnetic hard disk. Typically, voice-coil motors (VCM) 102 are used for controlling a hard drive's arm 104 motion across a magnetic hard disk 106. Because of the inherent tolerance (dynamic play) that exists in the placement of a recording head 108 by a VCM 102 alone, micro-actuators 110 are now being utilized to ‘fine-tune’ head 108 placement, as is described in U.S. Pat. No. 6,198,606. A VCM 102 is utilized for course adjustment and the micro-actuator then corrects the placement on a much smaller scale to compensate for the VCM's 102 (with the arm 104) tolerance. This enables a smaller recordable track width, increasing the ‘tracks per inch’ (TPI) value of the hard drive (increased drive density).

FIG. 2 provides an illustration of a micro-actuator as used in the art. Typically, a slider 202 (containing a read/write magnetic head; not shown) is utilized for maintaining a prescribed flying height above the disk surface 106 (See FIG. 1). Micro-actuators may have flexible beams 204 connecting a support device 206 to a slider containment unit 208 enabling slider 202 motion independent of the drive arm 104 (See FIG. 1). An electromagnetic assembly or an electromagnetic/ferromagnetic assembly (not shown) may be utilized to provide minute adjustments in orientation/location of the slider/head 202 with respect to the arm 104 (See FIG. 1).

Utilizing actuation means such as piezoelectrics (see FIG. 3), problems such as electrical sparking and particulate-enabled shortage can exist. It is therefore desirable to have a system for component treatment that prevents the above-mentioned problems in addition to having other benefits.

### BRIEF DESCRIPTION OF THE DRAWINGS

FIG. 1 provides an illustration of a drive arm configured to read from and write to a magnetic hard disk as used in the art.

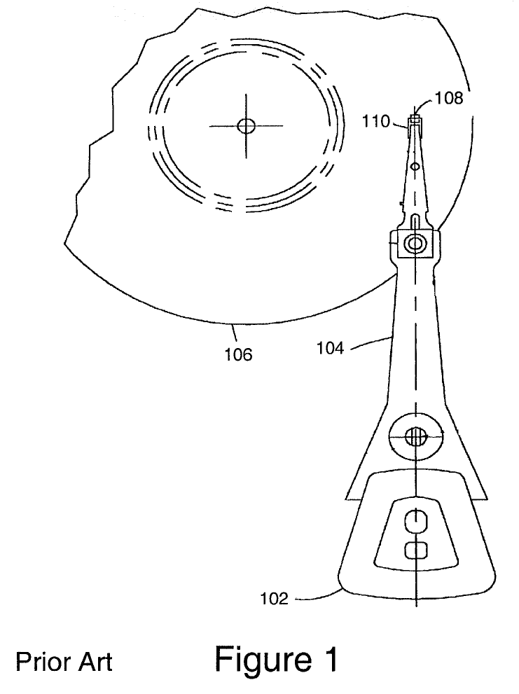

FIG. 2 provides an illustration of a micro-actuator as used in the art.

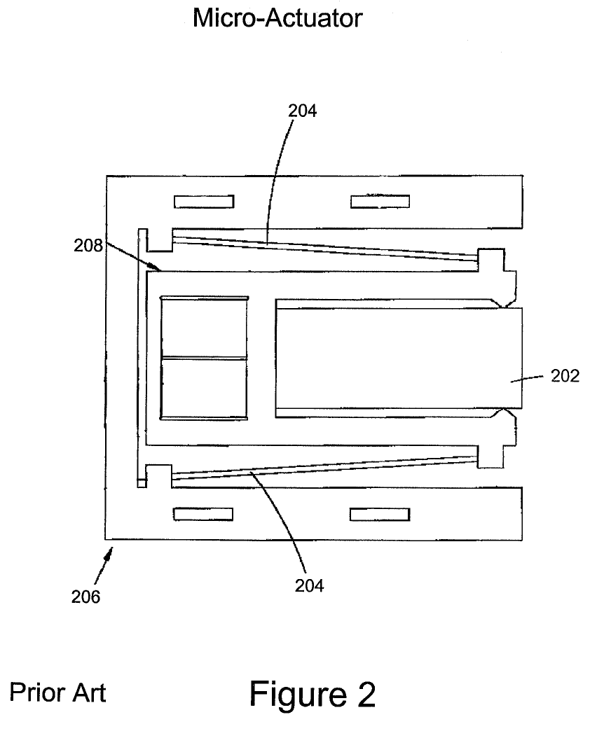

FIG. 3 provides an illustration of a ‘U’-shaped micro-actuator utilizing multi-layered piezoelectric transducers (PZT) to provide slider actuation.

FIG. 4 demonstrates the problem of electrical shortage between PZT layers.

FIG. 5 illustrates the damage caused by electrical sparking between PZT layers.

FIG. 6 illustrates the problem of electrical shortage between one or more PZT layers and the micro-actuator suspension.

FIG. 7 illustrates a dipping method for coating a micro-actuator under principles of the present invention.

FIG. 8 describes a pin applicator method for coating the piezoelectric structure under principles of the present invention.

FIG. 9 illustrates a method of coating a micro-actuator with a spray device under principles of the present invention.

FIG. 10 describes a method for coating which involves chemical vapor deposition.

### DETAILED DESCRIPTION

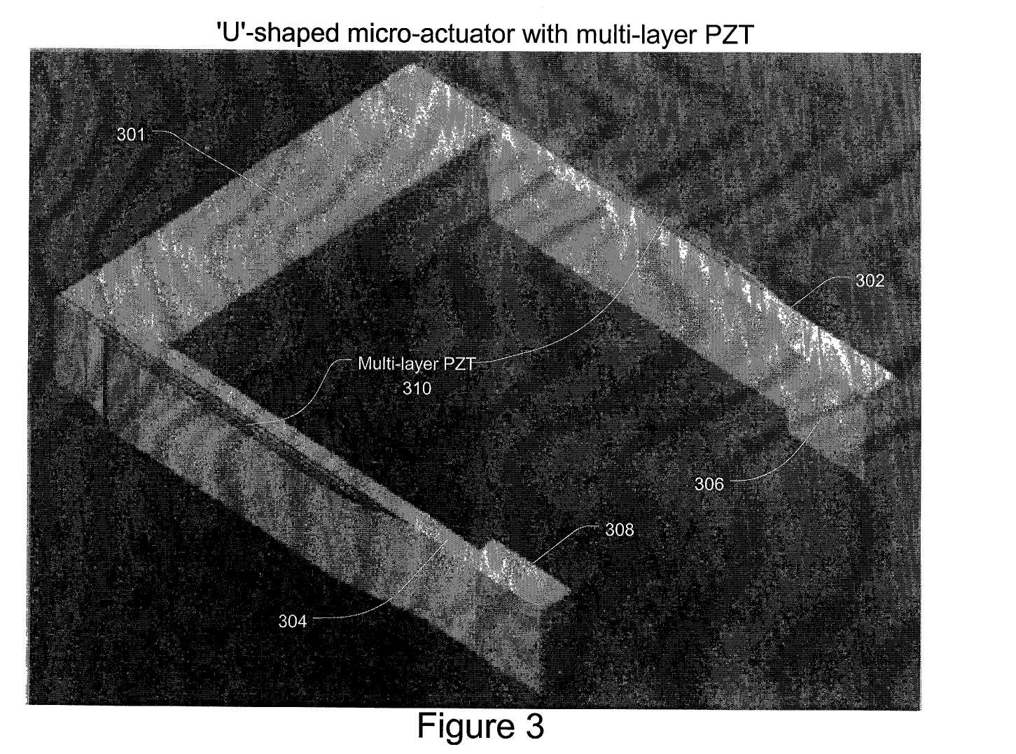

FIG. 3 provides an illustration of a ‘U’-shaped micro-actuator utilizing multi-layered piezoelectric transducers (PZT) to provide slider actuation. A slider (not shown) is attached between two arms 302, 304 of the micro-actuator 301 at two connection points 306, 308. Layers 310 of PZT material, such as Lead Zirconate Titanate, are bonded to the outside of each arm 302, 304. PZT material has an anisotropic structure whereby the charge separation between the positive and negative ions provides for electric dipole behavior. When a potential is applied across a poled piezoelectric material, Weiss domains increase their alignment proportional to the voltage, resulting in structural deformation (i.e. regional expansion/contraction) of the PZT material. As the PZT structures 310 bend (in unison), the arms 302,304 (which are bonded to the PZT structures 310), bend also, causing the slider (not shown) to adjust its position in relation to the micro-actuator 301 (for magnetic head fine adjustments).

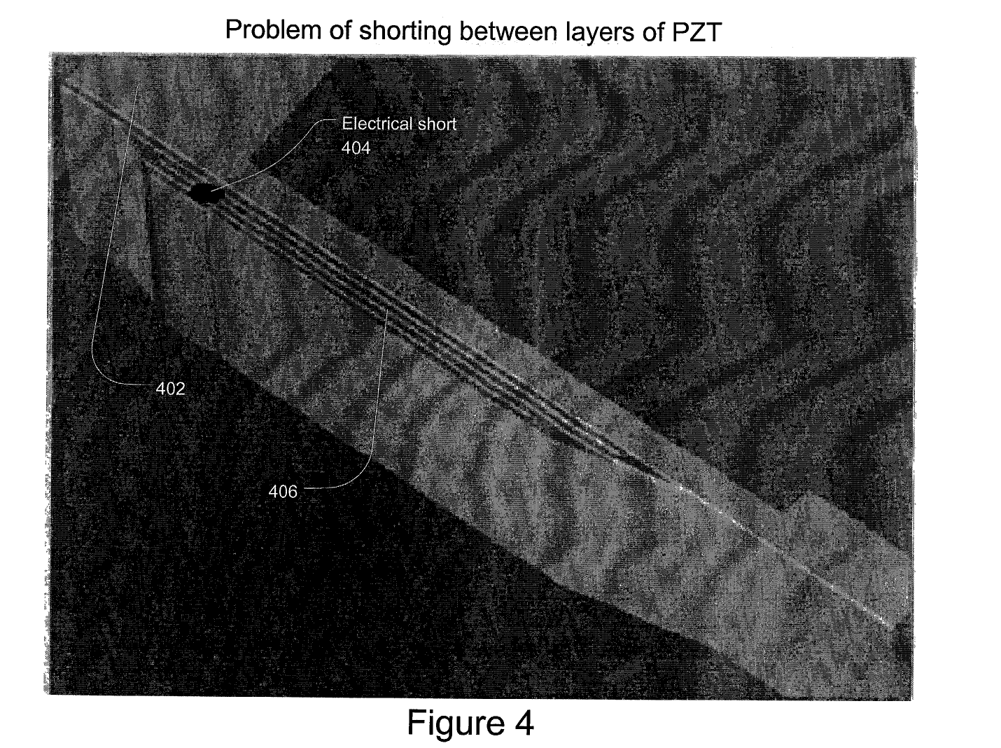

FIG. 4 demonstrates the problem of particulate-enabled shorting between PZT layers. During manufacture and/or drive operation, particles may be generated, and a particle(s) 404 may end up between layers of the PZT 406. Relative humidity can cause the particle(s) to absorb moisture from the air, enabling electrical conduction between PZT layers. This short 404 in the piezoelectric structure 406 can prevent its normal operation, adversely affecting micro-actuator 402 performance.

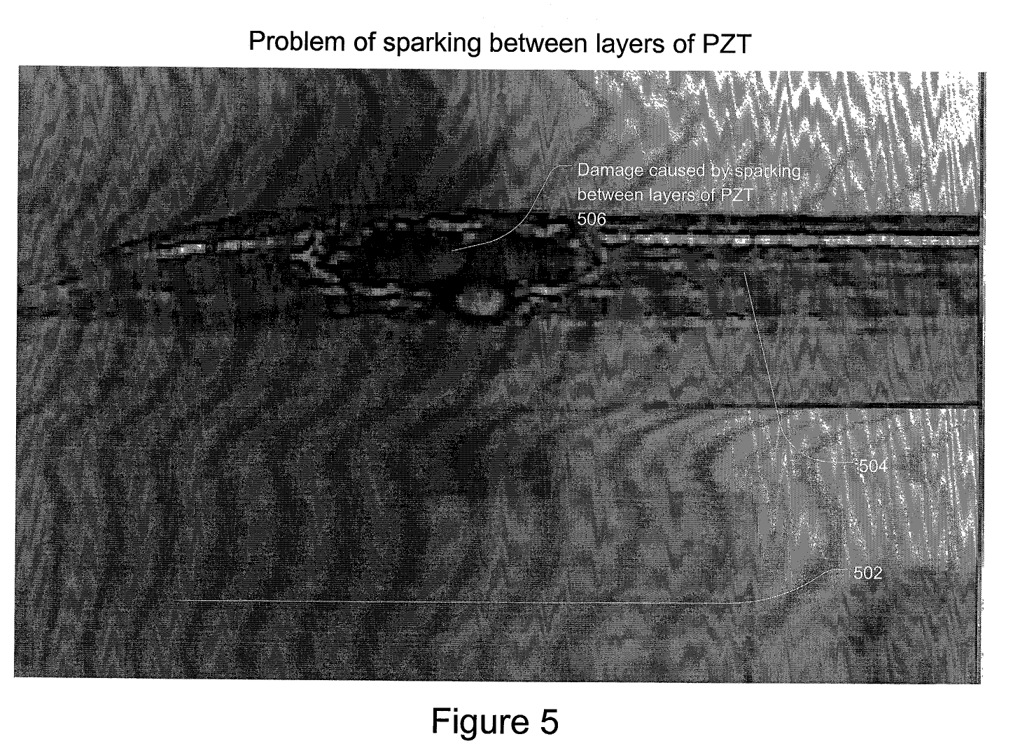

FIG. 5 illustrates the damage caused by electrical sparking between PZT layers. The scale of the micro-actuator 502, combined with the amount of piezoelectric voltage and the amount of moisture in the air, can cause electrical current to arc between layers of the piezoelectric structure 504, damaging 506 the structure. The greater the amount of humidity, the higher the risk for electrical spark due to the increased conductance (decreased insulation) of the air. This spark problem can be further aggravated by particulate accumulation, decreasing the gap distance for an arc between PZT layers 504.

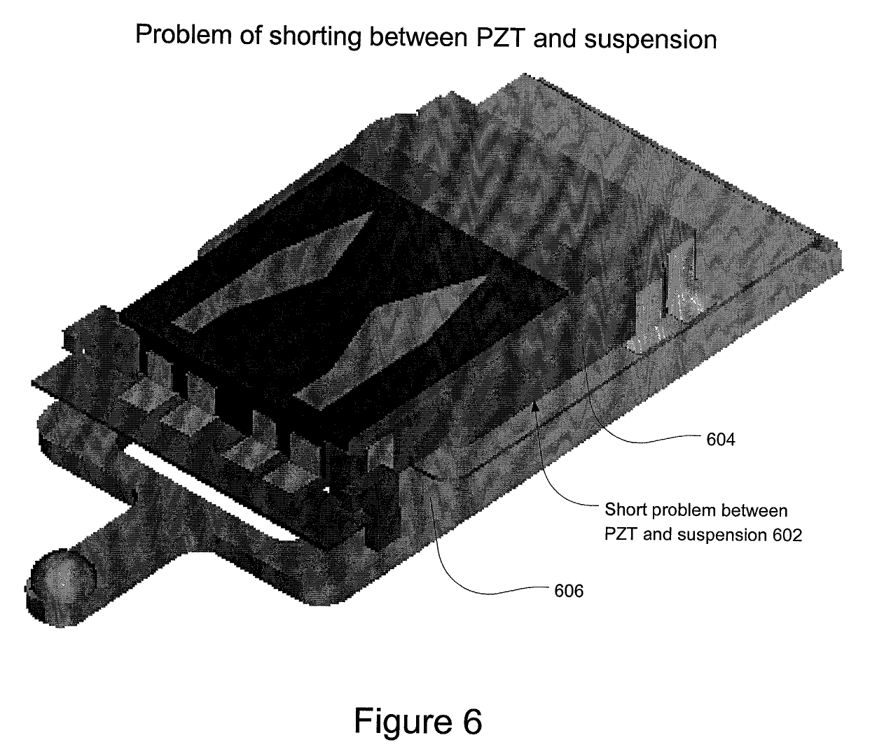

FIG. 6 illustrates the problem of electrical shortage between one or more PZT layers and the micro-actuator suspension (such as at a stainless steel portion). Similar to the problem of electrical shortage between PZT layers described in FIG. 4, it is likely for electrical current to short 602 between the piezoelectric structure 604 and the suspension 606.

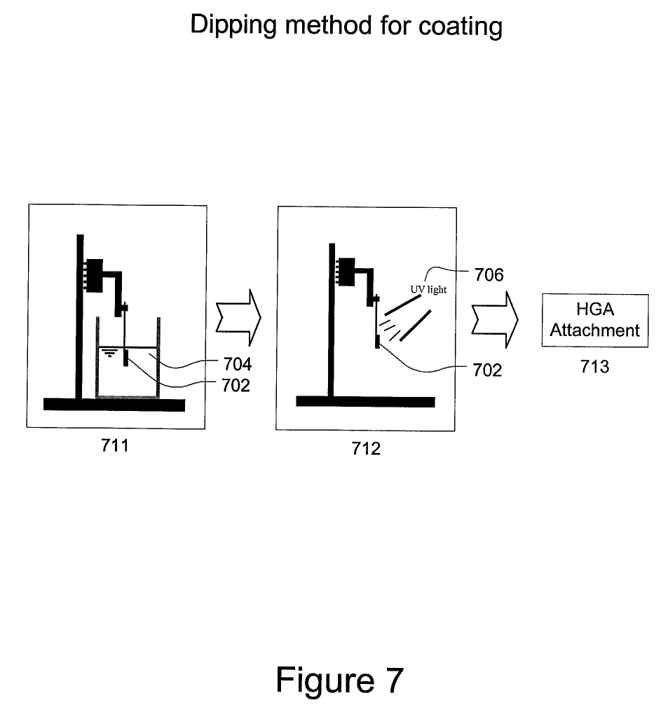

In order to prevent problems such as particulate-enabled shorting and electrical sparking (arcing) a micro-actuator is coated with a material such as an insulator under principles of the present invention. FIG. 7 illustrates a dipping method for coating a micro-actuator under principles of the present invention. In one embodiment, a micro-actuator 702 is first 711 lowered into a reservoir filled with coating material 704 to cover the surface of the micro-actuator 702. Next 712, in one embodiment, the micro-actuator 702 is exposed to ultraviolet (UV) light 706 to bond and dry the film of coating material remaining on the surface. Next 713, after the coating has dried, the micro-actuator is attached to a head gimbal assembly (HGA).

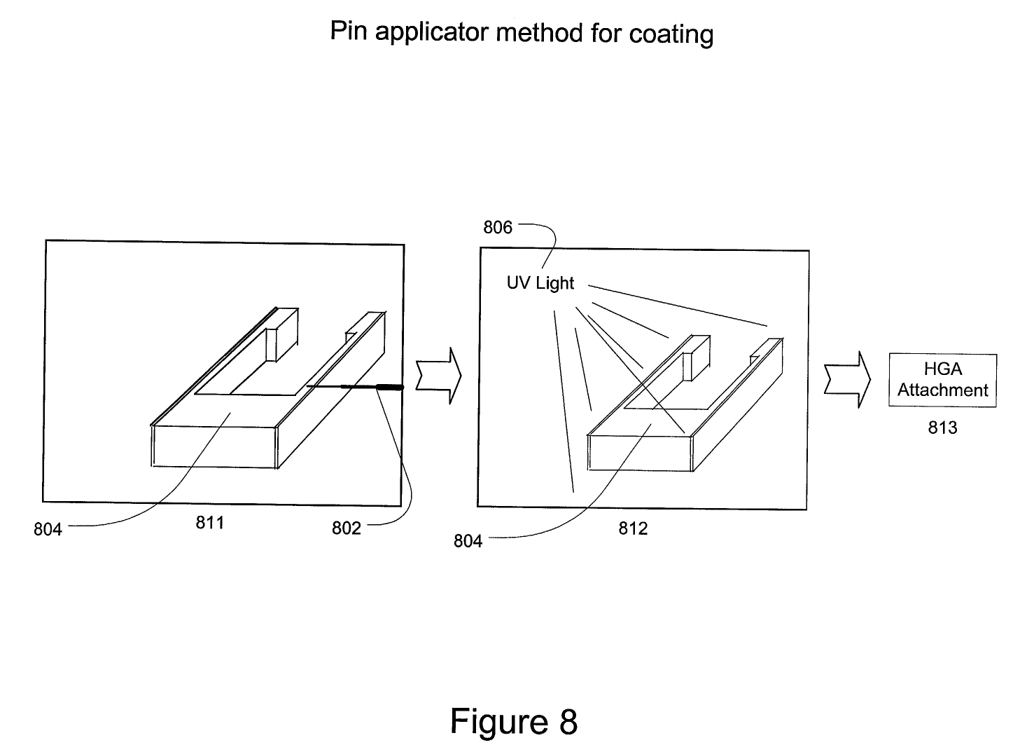

FIG. 8 describes a pin applicator method for coating the piezoelectric structure under principles of the present invention. First 811, in an embodiment, a pin applicator 802 with coating material is used to apply the coating material to desired areas, such as the surface of a piezoelectric structure 804. Next 812, in an embodiment, the micro-actuator 804 is exposed to UV light 806 to bond and dry the film of coating material remaining on the surface. Next 813, after the coating has dried, the micro-actuator is attached to the HGA.

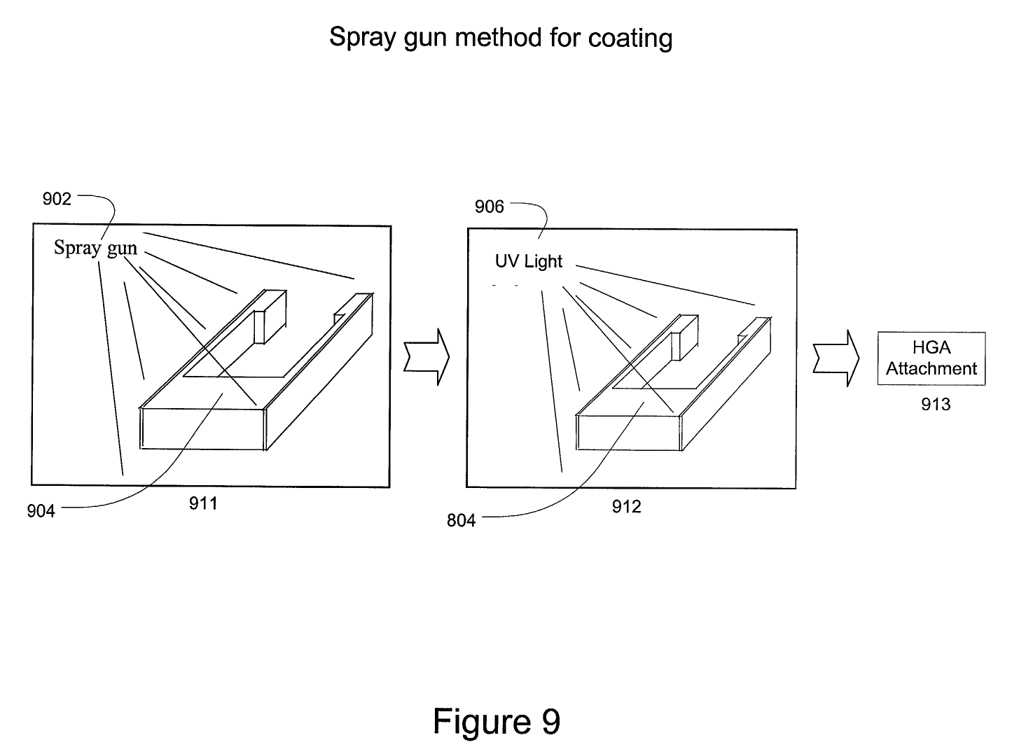

FIG. 9 illustrates a method of coating a micro-actuator with a spray device under principles of the present invention. First 911, in one embodiment, a spray gun 902 is utilized to coat the surface of a micro-actuator 904 with a material such as an insulator. Next 912, in an embodiment, the micro-actuator 904 is exposed to UV light 906 to bond and dry the film of coating material remaining on the surface. Next 813, after the coating has dried, the microactuator is attached to the HGA.

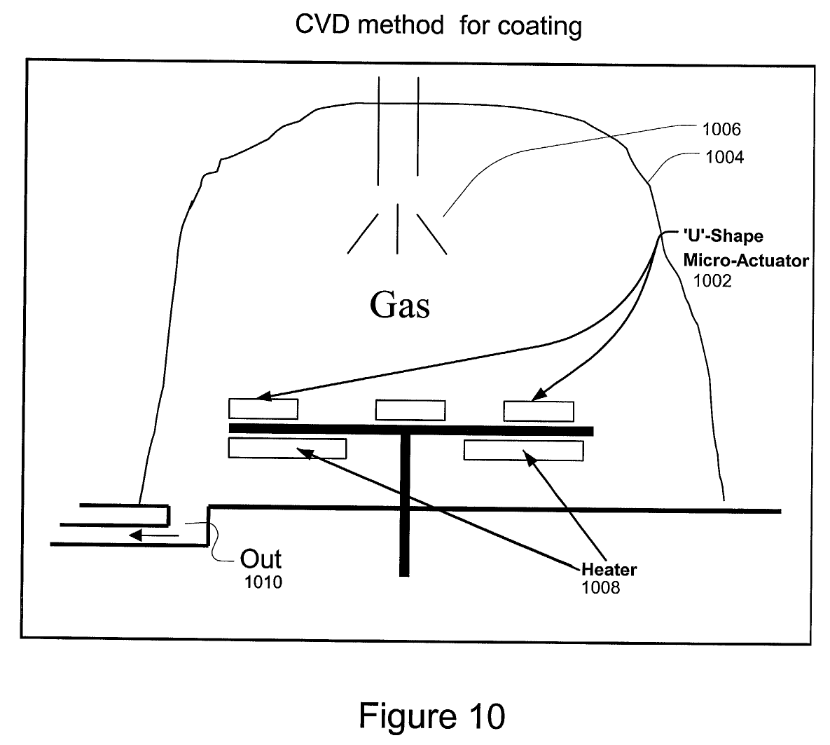

FIG. 10 describes a method for coating which involves chemical vapor deposition (CVD). In an embodiment, a micro-actuator 1002 is placed within a CVD chamber 1004. Next, a material such as an insulator 1006 is injected into the chamber 1004 in a vapor form while a platform holding the micro-actuator 1002 rotates, enabling a uniform thickness of material deposited on the surface of the micro-actuator 1002. Once a target material thickness is achieved, a heater 1008 is utilized to bond and dry the film of coating material remaining on the surface, and the surplus vapor is evacuated 1010.

Although several embodiments are specifically illustrated and described herein, it will be appreciated that modifications and variations of the present invention are covered by the above teachings and within the purview of the appended claims without departing from the spirit and intended scope of the invention.

1. A system to treat a piezoelectric component comprising:
a piezoelectric component adapted to be coupled to an actuator element; wherein
said piezoelectric component is to be coated with a first material, said first material being at least electrically insulative.

2. The system of claim 1, wherein the piezoelectric component and the actuator element are coated with said first material.

3. The system of claim 1, wherein the first material is to prevent an electrical short between a plurality of piezoelectric layers of said piezoelectric component.

4. The system of claim 3, wherein the first material is to prevent an electrical short between piezoelectric layers by isolating said piezoelectric component from a foreign body.

5. The system of claim 1, wherein the first material is to prevent an electrical spark between a plurality of piezoelectric layers of said piezoelectric component.

6. The system of claim 1, wherein the first material is to prevent an electrical short between one of said piezoelectric layers and a suspension assembly.

7. The system of claim 1, wherein the first material is a corrosion preventative.

8. The system of claim 1, wherein the first material is an adhesive.

9. The system of claim 8, wherein the first material is epoxy.

10. The system of claim 1, wherein the piezoelectric component is a piezoelectric transducer.

11. The system of claim 10, wherein the piezoelectric transducer is to deform to cause actuator motion.

12. The system of claim 1, wherein the actuator element is a magnetic hard drive micro-actuator.

13. The system of claim 12, wherein the micro-actuator is a ‘U’- shaped micro-actuator.

14. The system of claim 1, wherein the piezoelectric component is coated with said first material by dipping said component into said first material.

15. The system of claim 1, wherein the piezoelectric component is coated with said first material via direct application with an applicator pin.

16. The system of claim 1, wherein the piezoelectric component is coated with said first material via indirect application with a spray device.

17. The system of claim 1, wherein the piezoelectric component is coated with said first material via chemical vapor deposition (CVD).

18. The system of claim 17, wherein the piezoelectric component is coated with diamond-like carbon (DLC) via CVD.

19. A method to treat a piezoelectric component comprising:
coating with a first material a piezoelectric component, said piezoelectric component adapted to be coupled to an actuator element.

20. The method of claim 19, wherein said piezoelectric component is treated by coating with said first material a piezoelectric component and applying ultraviolet (UTV) light to said piezoelectric component.

21. The method of claim 19, wherein said piezoelectric component is treated by coating with said first material a piezoelectric component and applying heat to said piezoelectric component.

22. The method of claim 19, wherein the first material is to prevent an electrical short between a plurality of piezoelectric layers of said piezoelectric component.

23. The method of claim 19, wherein the first material is to prevent an electrical short between piezoelectric layers by isolating said piezoelectric component from a foreign body.

24. The method of claim 19, wherein the first material is to prevent an electrical spark between a plurality of piezoelectric layers of said piezoelectric component.

25. The method of claim 19, wherein the first material is to prevent an electrical short between one of said piezoelectric layers and a suspension assembly.

26. The method of claim 19, wherein the first material is a corrosion preventative.

27. The method of claim 19, wherein the first material is an adhesive.

28. The method of claim 27, wherein the first material is epoxy.

29. The method of claim 19, wherein the piezoelectric component is a piezoelectric transducer.

30. The method of claim 29, wherein the piezoelectric transducer is to deform to cause actuator motion.

31. The method of claim 19, wherein the actuator element is a magnetic hard drive ‘U’- shaped micro-actuator.

32. The method of claim 19, wherein the piezoelectric component is coated with said first material by dipping said component into said first material.

33. The method of claim 19, wherein the piezoelectric component is coated with said first material via direct application with an applicator pin.

34. The method of claim 19, wherein the piezoelectric component is coated with said first material via indirect application with a spray device.

35. The method of claim 19, wherein the piezoelectric component is coated with said first material via chemical vapor deposition (CVD).

36. The method of claim 35, wherein the piezoelectric component is coated with diamond-like carbon (DLC) via CVD.
